(19) United States
(12) Patent Application Publication
(10) Pub. No.: US 2003/0214990 A1
(43) Pub. Date: Nov. 20, 2003

(54) Semiconductor device

(75) Inventor: Tomoko Kadowaki, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/303,871

(22) Filed: Nov. 26, 2002

(30) Foreign Application Priority Data
May 20, 2002 (JP) 2002-144842

(51) Int. Cl. H01S 5/00

(52) U.S. Cl. 372/46; 372/45

(57) ABSTRACT

Disclosed herein is a semiconductor device for producing laser light from an active layer. The semiconductor device includes a ridge-shaped mesa including the active layer, current block layers formed so as to bury both sides of the mesa, a diffusion block layer formed on the mesa and the current block layers so as to be concatenated, and a p-InP clad layer formed on the diffusion block layer and containing a predetermined impurity. It is possible to restrain a reduction in the resistance of each current block layer due to the diffusion of the impurity of the p-InP clad layer into the current block layers and realize a high-speed operation of a laser with a modulator.

### BACKGROUND OF THE INVENTION

1. Field of the Invention

The present invention relates to a semiconductor device, and is particularly suitable for application to a laser with an optical modulator used in an ultrafast optical communication system or the like.

2. Background Art

In order to transmit high volumes of data by use of a semiconductor laser and an optical fiber, it is necessary to modulate the semiconductor laser at high speed. Therefore, there has been known a method of changing an injection current of the semiconductor laser used in a single mode to thereby perform direct modulation. Since, however, a wavelength variation (wavelength chirping) due to a variation in the density of an injected carrier is high, the present method cannot be used for high-speed modulation of 10 Gbps or more, for example.

Attention has been given to a method of modulating a semiconductor laser by an optical modulator having small wavelength chirping, as an alternative to the conventional direct modulation method. The laser used in this method is called generally a “laser with an optical modulator”. The laser with the optical modulator is one wherein a single mode semiconductor laser and a high-speed optical modulator for modulating the laser are brought into integration on one chip. Therefore, the laser with the optical modulator makes it unnecessary to provide circuits between the optical modulator and the laser and is high in practicality. Further, the laser with the optical modulator is extremely important as a key device for large-capacity optical communications.

In order to realize a high-speed operation of such a laser, it is necessary to reduce electric capacity of a modulator part and increase the resistance of an isolation part provided between a laser part and the modulator part. In addition, it also needs to have sufficient high reliability as a communication laser.

FIG. 27A is a perspective view showing a structure of a conventional laser with an optical modulator. FIG. 27B is a schematic cross-sectional view showing a cross section taken along line I-I′ shown in FIG. 27A. In FIGS. 27A and 27B, reference numeral 101 indicates an InP substrate, reference numeral 112 indicates an n-InP clad layer, reference numeral 103 indicates an absorption layer for the modulator, reference numeral 113 indicates a p-InP clad layer, reference numeral 105 indicates a mesa including an active layer 102 (unillustrated in FIGS. 27A and 27B) and the absorption layer 103, and reference numerals 106 indicate current block layers each comprising a high-resistance InP layer 106a and an n-InP layer 106b, respectively. Reference numeral 107 indicates a p-InP clad layer, reference numeral 108 indicates a p-InGaAs contact layer, and reference numerals 109 indicate mesa trenches (process mesa trenches), respectively.

A method of manufacturing the conventional laser with the optical modulator will be explained below with reference to FIGS. 22 through 27. FIGS. 22 through 27 are respectively schematic drawings showing the manufacturing method of the conventional laser in a process order, wherein FIG. 22, FIG. 23A, FIG. 24A, FIG. 25A, FIG. 26A and FIG. 27A are respectively perspective views of the laser. Further, FIG. 23B, FIG. 24B, FIG. 25B and FIG. 26B are schematic cross-sectional views respectively showing a cross section taken along I-I′ of FIG. 23A, a cross section taken along line I-I′ of FIG. 24A, a cross section taken along line I-I′ of FIG. 25A, and a cross section taken along line I-I′ of FIG. 26A. Here, the cross section taken along line I-I′ shows a cross section of an isolation part between a laser part and a modulator part.

As shown in FIG. 22, a predetermined crystal layer containing an n-InP clad layer 112, an active layer 102 for a laser and an absorption layer 103 for a modulator, and a p-InP clad layer 113 is first epitaxially grown on an InP substrate 101. Afterwards, an insulating film 104 such as a silicon oxide film (SiO₂ film) having a width of about 6 μm is formed thereon. With the insulating film 104 used as a mask, a mesa 105 containing the active layer 102 and the absorption layer 103 is formed by wet etching using an etchant such as HBr. The active layer 102 and the absorption layer 103 are formed on'the same layer on the n-InP clad layer 112. An area in which the active layer 102 is formed, serves as a laser part, whereas an area in which the absorption layer 103 is formed, serves as a modulator part.

As shown in FIG. 23A, the insulating film 104 used for the formation of the mesa 105 is next used as a selective growth mask. A high-resistance InP layer 106a having a thickness ranging from about 2 μm to about 3 μm, and an n-InP layer 106b having a thickness of about 1.0 μm are continuously embedded in and grown on each side face of the mesa 105 as a current block layer 106 by a MOCVD method. At this time, ferrum (Fe), for example, is used as a dopant for the high-resistance InP layer 106a, and sulfur (S), for example, is used as a dopant for the n-InP layer 106b.

The reason why the n-InP layer 106b is grown on the high-resistance InP layer 106a, will now be described. In a subsequent process as will be described later, a p-InP clad layer 107 is formed on each of the current block layers 106. However, if the p-InP clad layer 107 is directly grown on the high-resistance InP layer 106a, then Zn corresponding to a dopant of the p-InP clad layer 107 and Fe corresponding to a dopant of the high-resistance InP layer 106a are mutually diffused. The resistance of the high-resistance InP layer 106a is reduced due to the diffusion of Zn into the high-resistance InP layer 106a. However, owing to the growth of the n-InP layer 106b between the p-InP clad layer 107 and the high-resistance InP layer 106a, the n-InP layer 106b will function as a hole trap layer which traps Zn to diffuse from the p-InP clad layer 107 to each high-resistance InP layer 106a. It is therefore possible to prevent a resistance reduction produced due to the diffusion of Zn into the high-resistance InP layer 106a.

Incidentally, the cross section (cross section of isolation part) taken along line I-I′ of FIG. 23A assumes the same shape as an end surface on the modulator side shown in FIG. 23A as illustrated in FIG. 23B in this stage.

As shown in FIG. 24A, the position corresponding to the isolation part is dry-etched to a predetermined depth to thereby remove the n-InP layers 106b of the isolation part. In this etching, the n-InP layer 106b lying in an area provided inside from each mesa trench 109 defined in a subsequent process is removed. A cross section of the isolation part subsequent to the removal of the n-InP layers 106b is represented as shown in FIG. 24(b). While the n-InP layer 106b is an n type and low in resistance, high isolation resistance can be obtained by removing the n-InP layers 106b from the isolation part in this way.

As shown in FIGS. 25A and 25B, a p-InP clad layer 107 and a p-InGaAs contact layer 108 are next grown on the whole surface of a wafer. Consequently, the high-resistance InP layers 106a and the p-InP clad layer 107 are brought into close contact with each other in the isolation part.

As shown in FIGS. 26A and 26B, the p-InGaAs contact layer 108 of the isolation part is next removed by wet etching using an etchant such as tartaric acid. The reason why the p-InGaAs contact layer 108 of the isolation part is removed, is also similar to the reason for removing the n-InP layers 106b of the isolation part and is to obtain high isolation resistance in the isolation part.

Finally, mesa trenches 109 each having a width ranging from about 5 μm to about 7 μm are defined as shown in FIGS. 27A and 27B by a method such as etching. Consequently, the laser with the optical modulator shown in FIGS. 27A and 27B is completed. A cross section of the isolation part of the completed laser with the optical modulator corresponds to a structure shown in FIG. 27B. Owing to the removal of the n-InP layers 106b, the removal of the p-InGaAs contact layer 108 and the formation of the process mesa trenches 109, the periphery of the mesa 105 including the n-InP clad layer 112, active layer 102, absorption layer 103 and p-InP clad layer 113 is covered with a high-insulative layer, so that an increase in separation resistance is achieved.

Thus, the conventional laser with the optical modulator executes processes such as the removal of the n-InP layers 106b of the isolation part, the removal of the p-InGaAs contact layer 108 thereof, etc. to increase the separation resistance of the isolation part located between the laser and the modulator.

However, the conventional laser with the optical modulator has caused a new problem due to the removal of the n-InP layers 106b of the isolation part. This is a problem caused by the direct contact between each high-resistance InP layer 106a and the p-InP clad layer 107 due to the removal of the n-InP layers 106b of the isolation part. When the high-resistance InP layer 106a and the p-InP clad layer 107 are brought into contact with each other, Fe corresponding to a dopant of the high-resistance InP layer 106a and Zn corresponding to a dopant of the p-InP clad layer 107 are mutually diffused as shown in FIG. 28A. The high-resistance InP layer 106a is reduced in resistance due to the diffusion of Zn corresponding to the p-type dopant into the high-resistance InP layer 106a. As a result, a problem arose in that the separation resistance between the laser and the modulator was lowered and hence a high-frequency leak occurred, thereby interfering with a high-speed operation.

Further, another problem arose even in the modulator part. As described above, the modulator part is structurally designed in such a manner that owing to the provision of the n-InP layer 106b between the p-InP clad layer 107 and each of the high-resistance InP layers 106a, the n-InP layer 106b traps Zn to diffuse from the p-InP clad layer 107 to the high-resistance InP layer 106a to thereby prevent a reduction in the resistance of the high-resistance InP layer 106a.

In an actual manufacturing process, however, a leading end of each n-InP layer 106b might be spaced away from each side face of a mesa 105 as shown in FIG. 28B. When a high-resistance InP layer 106a is formed on the side face of the mesa 105 with a predetermined thickness upon formation of the high-resistance InP layer 106a and the n-InP layer 106b, for example, such a state as illustrated in FIG. 28B will occur.

In this case, the p-InP clad layer 107 and the high-resistance InP layer 106a are brought into direct contact with each other between the leading end of the n-InP layer 106b and the side face of the mesa 105, so that Fe corresponding to the dopant in the high-resistance InP layer 106a and Zn corresponding to the dopant contained in the p-InP clad layer 107 are mutually diffused. Therefore, Zn will compensate for Fe contained in the high-resistance InP layer 106a, so that the density of Fe contained in the high-resistance InP layer 106a is effectively lowered. This results in the exertion of an influence equivalent to the fact that each high-resistance InP layer 106a has been made thin in thickness. A problem arose in that since the capacitance was generally inversely proportional to the thickness, the capacity of the modulator part would increase due to the mutual diffusion of the dopants.

Further, the laser part and the modulator part have also involved a problem that Fe corresponding to the dopant of the high-resistance InP layer 106a and Zn corresponding to the dopant of the p-InP clad layer 107 are mutually diffused to thereby reduce the resistance of the high-resistance InP layer 106a of each current block layer 106. Further, a problem also arose in that when the dopants were diffused into the mesa 105 including the active layer 102, the absorption layer 103, etc., characteristic degradation such as a reduction in the efficiency of a device, and deterioration in reliability would occur.

Thus, the conventional laser with the optical modulator has involved a problem that due to the mutual diffusion of Zn and Fe, the separation resistance between the laser and the modulator is lowered or the capacity of the modulator increases, so that the high-speed operation of the laser is impaired and reliability thereof is further deteriorated.

### SUMMARY OF THE INVENTION

The present invention has been made to solve the foregoing problems and aims to suppress mutual diffusion of dopants, realize a high-speed operation of a laser with a modulator and enhance reliability thereof.

According to one aspect of the present invention, a semiconductor device for producing laser light from an active layer comprises a ridge-shaped mesa portion, current block layers, a diffusion block layer, and a conductive layer. The ridge-shaped mesa portion includs the active layer. The current block layers are formed so as to bury both sides of the mesa portion. The diffusion block layer is formed on the mesa portion and the current block layers in a continuous form. The conductive layer is formed on the diffusion block layer and containing a predetermined impurity.

According to another aspect of the present invention, a semiconductor device for producing laser light from an active layer comprises a ridge-shaped mesa portion, current block layers, a conductive layer, and a diffusion block layer. The ridge-shaped mesa portion includs the active layer. The current block layers are formed so as to bury both sides of the mesa portion. The conductive layer is formed on the mesa portion and the current block layers and containing a predetermined impurity. The current block layers have an insulative first layer for covering each side portion of the mesa portion and a second layer of conductivity type opposite to the conductive layer. The second layer is formed on the first layer. The diffusion block layer is formed between the first layer and the second layer.

According to another aspect of the present invention, a semiconductor device for producing laser light from an active layer comprises a ridge-shaped mesa portion, current block layers, a diffusion block layer, and a conductive layer. The ridge-shaped mesa portion includs the active layer. The current block layers are formed so as to bury both sides of the mesa portion. The diffusion block layer is formed between at least each side portion of the mesa portion and the current block layer. The conductive layer is formed over the mesa portion and the current block layers and containing a predetermined impurity.

Since diffusion block layers are continuously formed on a mesa portion and current block layers, an impurity of a conductive layer can be prevented from being diffused into the current block layers. It is thus possible to inhibit a reduction in the resistance of each current block layer and realize a high-speed operation of a laser.

Since the diffusion block layer is formed between the first layer and second layer of each current block layer, the diffusion of the impurity of the conductive layer into the first layer of the current block layer can be inhibited. Further, the second layer is capable of trapping the impurity of the conductive layer. It is thus possible to suppress a reduction in the resistance of the current block layer and realize a high-speed operation of a laser.

Since the diffusion block layer is formed between each side of a mesa portion and its corresponding current block layer, the diffusion of an impurity of a conductive layer into the mesa portion can be inhibited. It is thus possible to suppress characteristic degradation such as a reduction in the efficiency of a device, and deterioration in reliability.

Other and further objects, features and advantages of the invention will appear more fully from the following description.

### BRIEF DESCRIPTION OF THE DRAWINGS

FIG. 1 is a perspective view showing a manufacturing method of the laser according to a first embodiment.

FIG. 2A is a perspective view showing the manufacturing method of the laser according to the first embodiment.

FIG. 2B is a schematic cross-sectional view showing a cross section taken along line I-I′ shown in FIG. 2A.

FIG. 3A is a perspective view showing the manufacturing method of the laser according to the first embodiment.

FIG. 3B is a schematic cross-sectional view showing a cross section taken along line I-I′ shown in FIG. 3A.

FIG. 4A is a perspective view showing the manufacturing method of the laser according to the first embodiment.

FIG. 4B is a schematic cross-sectional view showing a cross section taken along line I-I′ shown in FIG. 4A.

FIG. 5A is a perspective view showing the manufacturing method of the laser according to the first embodiment.

FIG. 5B is a schematic cross-sectional view showing a cross section taken along line I-I′ shown in FIG. 5A.

FIG. 6A is a perspective view showing the laser with an optical modulator, according to the first embodiment.

FIG. 6B is a schematic cross-sectional view showing a cross section taken along line I-I′ shown in FIG. 6A.

FIG. 7A shows a cross section of the isolation part of the completed laser with the optical modulator, according to the first embodiment.

FIG. 7B shows a cross section taken along line II-II′ of FIG. 6A and also illustrates a cross section of the modulator part of the completed laser with the optical modulator.

FIG. 8 is a perspective view showing a manufacturing method of the laser according to a second embodiment.

FIG. 9A is a perspective view showing the manufacturing method of the laser according to the second embodiment.

FIG. 9B is a schematic cross-sectional view showing a cross section taken along line I-I′ shown in FIG. 9A.

FIG. 10A is a perspective view showing the manufacturing method of the laser according to the second embodiment.

FIG. 10B is a schematic cross-sectional view showing a cross section taken along line I-I′ shown in FIG. 10A.

FIG. 11A is a perspective view showing the manufacturing method of the laser according to the second embodiment.

FIG. 11B is a schematic cross-sectional view showing a cross section taken along line I-I′ shown in FIG. 11A.

FIG. 12A is a perspective view showing the manufacturing method of the laser according to the second embodiment.

FIG. 12B is a schematic cross-sectional view showing a cross section taken along line I-I′ shown in FIG. 12A.

FIG. 13A is a perspective view showing the laser with an optical modulator, according to the second embodiment.

FIG. 13B is a schematic cross-sectional view showing a cross section taken along line I-I′ shown in FIG. 13A.

FIG. 14A is a schematic cross-sectional view showing a cross section of the isolation part of the completed laser in a manner similar to FIG. 13B.

FIG. 14B shows a cross section taken along line II-II′ of FIG. 13A and also illustrates a cross section of the modulator part of the completed laser with the optical modulator.

FIG. 15 is a perspective view showing a manufacturing method of the laser according to a third embodiment.

FIG. 16A is a perspective view showing the manufacturing method of the laser according to the third embodiment.

FIG. 16B is a schematic cross-sectional view showing a cross section taken along line I-I′ shown in FIG. 16A.

FIG. 17A is a perspective view showing the manufacturing method of the laser according to the third embodiment.

FIG. 17B is a schematic cross-sectional view showing a cross section taken along line I-I′ shown in FIG. 17A.

FIG. 18A is a perspective view showing the manufacturing method of the laser according to the third embodiment.

FIG. 18B is a schematic cross-sectional view showing a cross section taken along line I-I′ shown in FIG. 18A.

FIG. 19A is a perspective view showing the manufacturing method of the laser according to the third embodiment.

FIG. 19B is a schematic cross-sectional view showing a cross section taken along line I-I′ shown in FIG. 19A.

FIG. 20A is a perspective view showing the laser with an optical modulator, according to the third embodiment.

FIG. 20B is a schematic cross-sectional view showing a cross section taken along line I-I′ shown in FIG. 20A.

FIG. 21 shows a cross section taken along line II-II′ of FIG. 20A and also illustrates a cross section of the modulator part of the completed laser with the optical modulator.

FIG. 22 is a perspective view showing a manufacturing method of the conventional laser.

FIG. 23A is a perspective view showing the manufacturing method of the conventional laser.

FIG. 23B is a schematic cross-sectional view showing a cross section taken along line I-I′ shown in FIG. 23A.

FIG. 24A is a perspective view showing the manufacturing method of the conventional laser.

FIG. 24B is a schematic cross-sectional view showing a cross section taken along line I-I′ shown in FIG. 24A.

FIG. 25A is a perspective view showing the manufacturing method of the conventional laser.

FIG. 25B is a schematic cross-sectional view showing a cross section taken along line I-I′ shown in FIG. 25A.

FIG. 26A is a perspective view showing the manufacturing method of the conventional laser.

FIG. 26B is a schematic cross-sectional view showing a cross section taken along line I-I′ shown in FIG. 26A.

FIG. 27A is a perspective view showing a structure of the conventional laser with an optical modulator.

FIG. 27B is a schematic cross-sectional view showing a cross section taken along line I-I′ shown in FIG. 27A.

FIGS. 28A and 28B show problems caused by the conventional laser with the optical modulator.

### DETAILED DESCRIPTION OF THE PREFERRED EMBODIMENTS

Several embodiments of the present invention will hereinafter be described in detail with reference to the accompanying drawings. Incidentally, the present invention is not limited to or by the following embodiments. In the respective drawings, the same or corresponding portions are respectively identified by the same reference numerals and the description of certain common portions will be suitably simplified or omitted.

First Embodiment

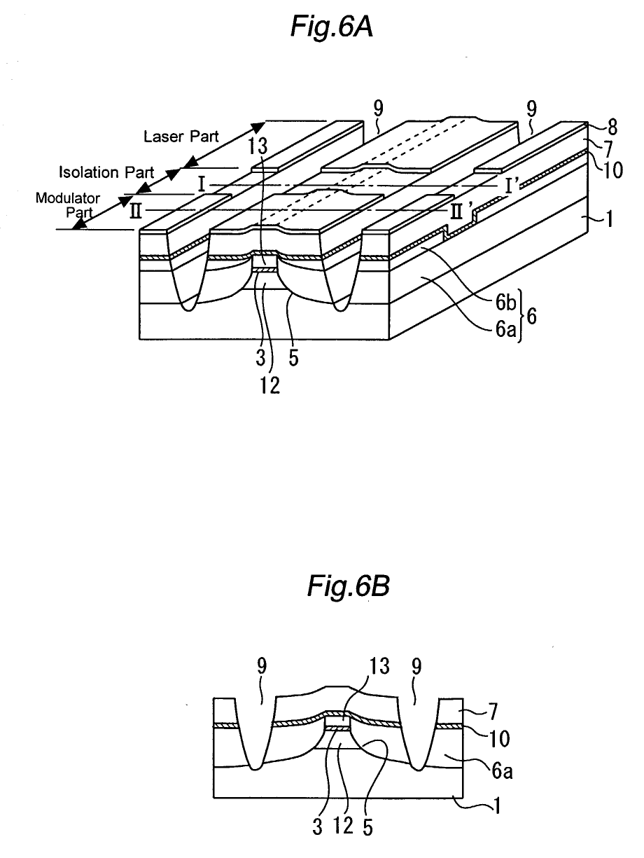

FIGS. 6A and 6B are schematic drawings showing a laser with an optical modulator, according to the first embodiment. Here, FIG. 6A is a perspective view of the laser, and FIG. 6B is a schematic cross-sectional view showing a cross section taken along line I-I′ in FIG. 6A, respectively.

As shown in FIGS. 6A and 6B, the laser comprises an InP substrate 1, an n-InP clad layer 12, an active layer 2 (unillustrated in FIGS. 6A and 6B), an absorption layer 3, a p-InP clad layer 13, a mesa 5 (AR mesa) including an active layer 2 and an absorption layer 3, current block layers 6 each comprised of a high-resistance InP layer 6a and an n-InP layer 6b, a p-InP clad layer 7, a p-InGaAs contact layer 8, and process mesa trenches 9.

A p-InGaAsP diffusion block layer 10 is formed so as to cover the top of the mesa 5 and the uppermost surfaces of the current block layers 6. The p-InGaAsP diffusion block layer 10 is formed so as to cover the top of the mesa 5 and the upper portions of the high-resistance InP layers 6a in an isolation part and the top of the mesa 5 and the upper portions of the n-InP layers 6b in a modulator part and a laser part.

Since the p-InGaAsP diffusion block layer 10 is formed so as to cover the uppermost surfaces of the current block layers 6 in this way, the p-InP clad layer 7 can be inhibited from making direct contact with the high-resistance InP layers 6a. It is thus possible to suppress mutual diffusion of dopants contained in the p-InP clad layer 7 and the high-resistance InP layers 6a.

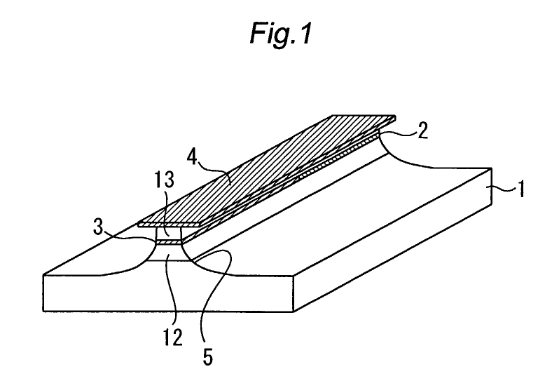

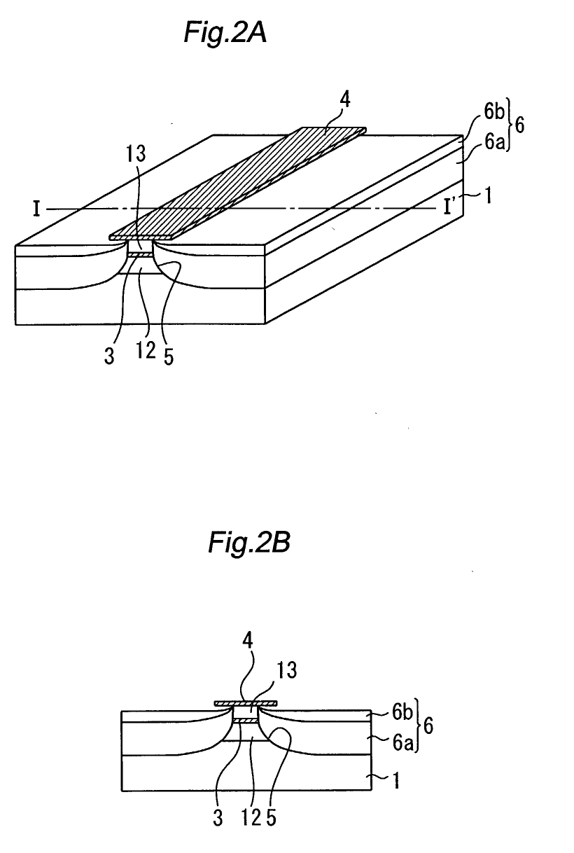

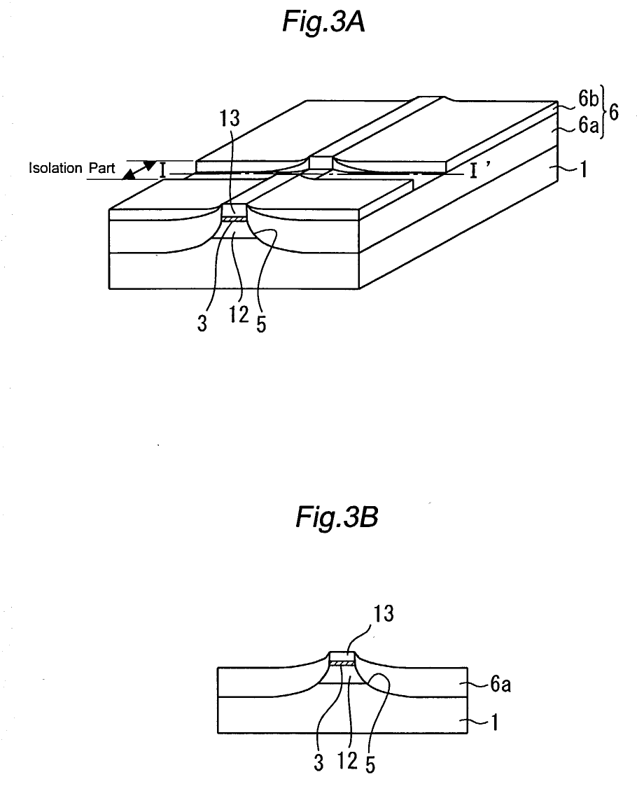

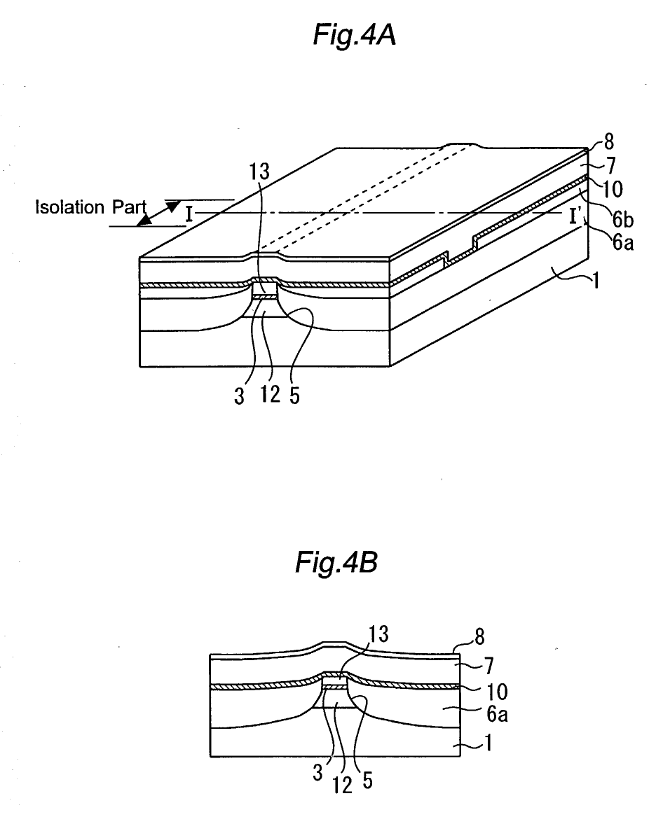

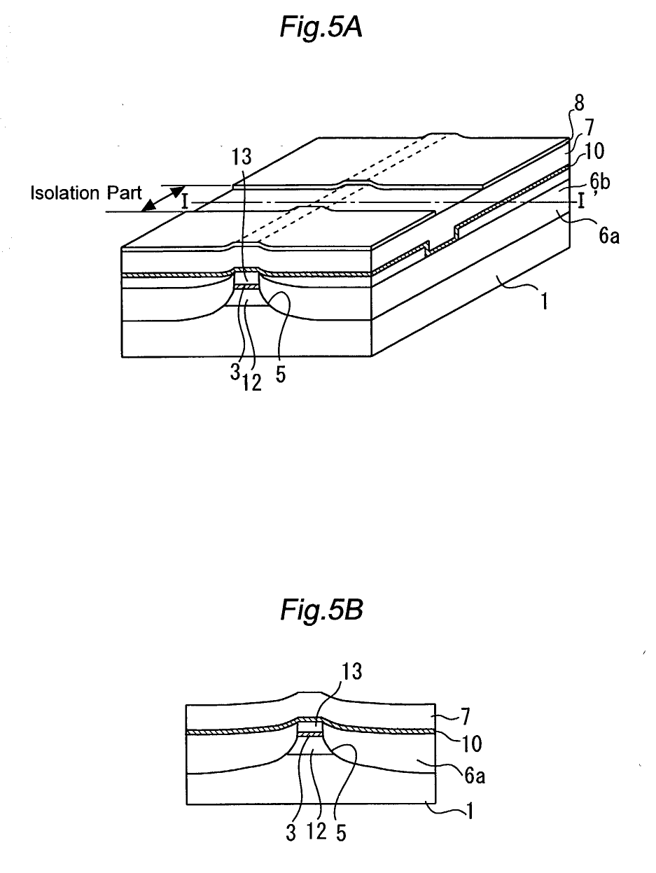

A method of manufacturing the laser according to the first embodiment will be explained below based on FIGS. 1 through 6. FIGS. 1 through 6 are respectively schematic drawings showing the manufacturing method of the laser according to the first embodiment in a process order, wherein FIG. 1, FIG. 2A, FIG. 3A, FIG. 4A, FIG. 5A and FIG. 6A are respectively perspective views of the laser. Further, FIG. 2B, FIG. 3B, FIG. 4B, FIG. 5B and FIG. 6B are schematic cross-sectional views respectively showing a cross section taken along I-I′ of FIG. 2A, a cross section taken along line I-I′ of FIG. 3A, a cross section taken along line I-I′ of FIG. 4A, a cross section taken along line I-I′ of FIG. 5A, and a cross section taken along line I-I′ of FIG. 6A. Here, the cross section taken along line I-I′ shows a cross section of the isolation part between the laser and the modulator part.

As shown in FIG. 1, a predetermined crystal layer containing an n-InP clad layer 12, an active layer 2 for a laser and an absorption layer 3 for a modulator, and a p-InP clad layer 13 is first epitaxially grown on an InP substrate 1. Afterwards, an insulating film 4 such as a silicon oxide film (SiO₂ film) having a width of about 6 μm is formed thereon. With the insulating film 4 as a mask, a plateau type mesa 5 containing the active layer 2 and the absorption layer 3 is formed by wet etching using an etchant such as hydrogen bromide (HBr). At this time, for example, the depth of the mesa 5 results in about 4 μm, and the width of the active layer 2 or the absorption layer 3 reaches about 1.3 μm. The active layer 2 and the absorption layer 3 are formed on the same layer or hierarchy on the n-InP clad layer 12. An area in which the active layer 2 is formed, serves as a laser part, whereas an area in which the absorption layer 3 is formed, serves as a modulator part.

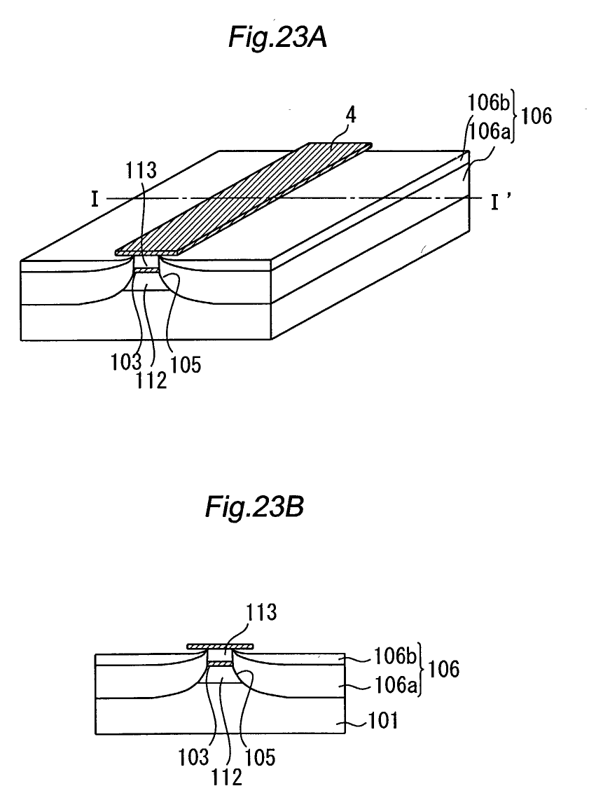

As shown in FIG. 2A, the insulating film 4 used for the formation of the mesa 5 is next used as a selective growth mask. a high-resistance InP layer 6a having a thickness ranging from about 2 μm to about 3 μm, and an n-InP layer 6b having a thickness of about 1.0 μm are continuously embedded in and grown on each side face of the mesa 5 as a current block layer 6 by a MOCVD method. At this time, ferrum (Fe), for example, is used as a dopant for the high-resistance InP layer 6a, and sulfur (S), for example, is used as a dopant for the n-InP layer 6b. Incidentally, the reason why the n-InP layer 6b is grown on the high-resistance InP layer 6a, is as described in FIGS. 23A and 23B.

Incidentally, the cross section (cross section of isolation part) taken along line I-I′ of FIG. 2A assumes the same shape as an end surface on the modulator side shown in FIG. 2A as illustrated in FIG. 2B in this stage.

As shown in FIG. 3A, the position corresponding to the isolation part is dry-etched to a predetermined depth to thereby remove the n-InP layer 6b of the isolation part. The amount of etching may preferably be set to a depth of about 0.6 μm to remove each n-Inp layer 6b lying in a region or area provided inside from each process mesa trench defined in a subsequent process. A cross section of the isolation part subsequent to the removal of the n-InP layers 6b is represented as shown in FIG. 3B. Removing the n-InP layers 6b low in resistance from the isolation part in this way allows acquirement of high isolation resistance.

As shown in FIGS. 4A and 4B, an epitaxial growth for the third time is next carried out to grow a p-InGaAsP diffusion block layer 10 so as to cover the top of the mesa 5 and the n-InP layers 6b of the uppermost surfaces of the current block layers 6. Afterwards, a p-InP clad layer 7 and a p-InGaAs contact layer 8 are grown.

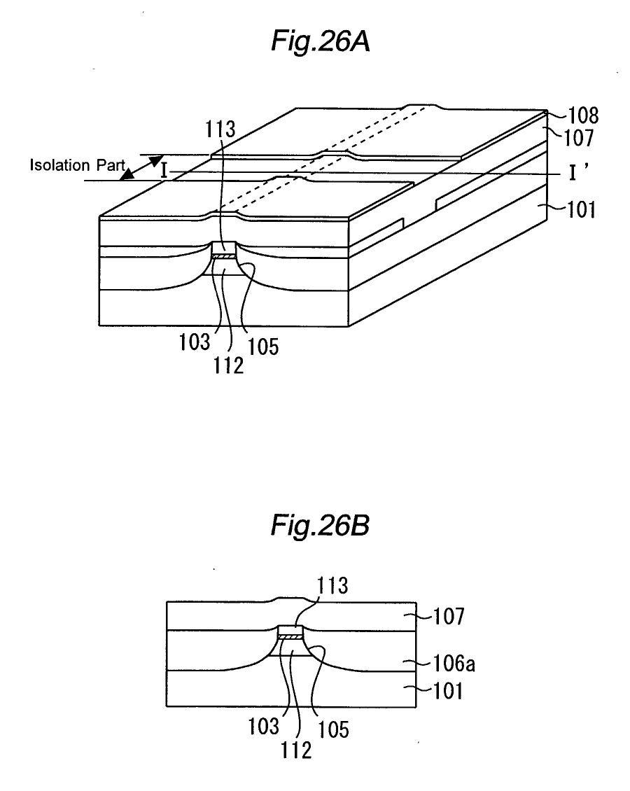

As shown in FIGS. 5A and 5B, the p-InGaAs contact layer 8 of the isolation part is next removed by etching. Incidentally, the reason why the p-InGaAs contact layer 8 of the isolation part is removed by etching, is as described in FIGS. 26A and 26B.

Next, mesa trenches 9 each having a width ranging from about 5 μm to about 7 μm are next provided as shown in FIGS. 6A and 6B, whereby the laser with the optical modulator, according to the present embodiment is completed.

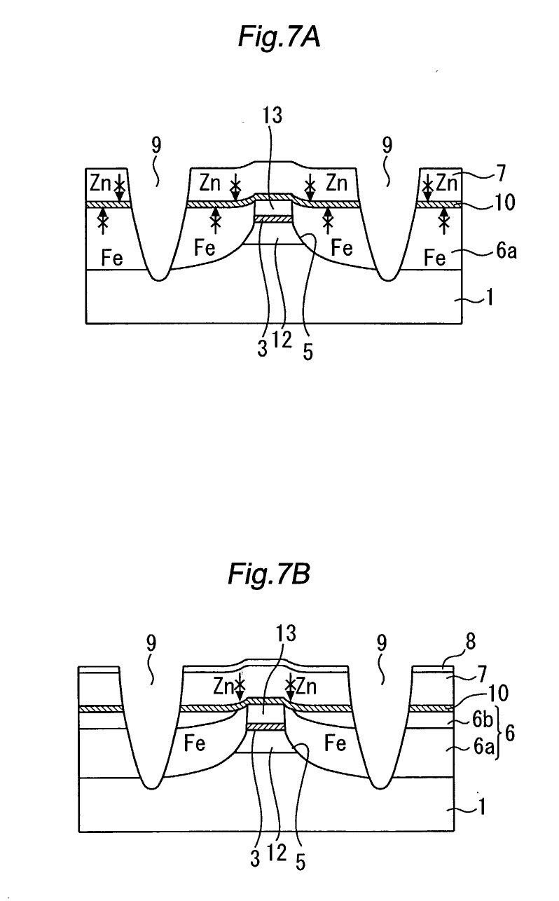

FIG. 6B and FIG. 7A respectively show a cross section of the isolation part of the completed laser with the optical modulator. As shown in FIG. 6B, the first embodiment has such a structure that the p-InGaAsP diffusion block layer 10 is inserted between each high-resistance InP layer 6a doped with Fe and the p-InP clad layer 7 doped with Zn. Since InGaAsP is higher several-fold than InP in solid solubility of Zn, it absorbs Zn to diffuse into the Fe-doped high-resistance InP layer 6a. As a result, the mutual diffusion of Zn and Fe can be prevented as shown in FIG. 7A. It is thus possible to restrain a reduction in isolation resistance due to the diffusion of Zn into the high-resistance InP layer 6a.

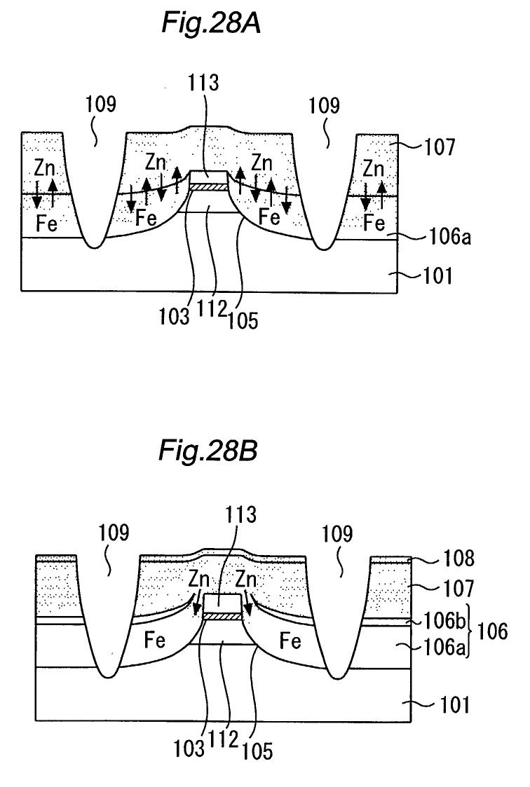

FIG. 7B shows a cross section taken along line II-II′ of FIG. 6A and also illustrates a cross section of the modulator part of the completed laser with the optical modulator. The p-InGaAsP diffusion block layer 10 is provided so as to cover the top of the mesa 5 and the n-InP layer 6b of the uppermost surface of each current block layer 6 even in the case of the modulator part. Therefore, even when the leading end of each n-InP block layer 6b is formed away from the side face of the mesa 5 as described in FIG. 28B, the high-resistance InP layer 6a exposed to each side face of the mesa 5 can be reliably covered with the p-InGaAsP diffusion block layer 10. Since the pInGaAsP diffusion block layer 10 absorbs Zn to diffuse into the Fe-doped high-resistance InP layer 6a, thus making it possible to suppress an increase in the capacitance of the modulator part due to the mutual diffusion of Fe contained in the high-resistance InP layer 6a and Zn contained in the p-InP clad layer 7.

According to the first embodiment as described above, the p-InGaAsP diffusion block layer 10 high in solid solubility for Zn is formed so as to cover the top of the mesa 5 and the uppermost surface of each current block. layer 6. It is therefore possible to inhibit the p-InP clad layer 7 from directly contacting the high-resistance InP layers 6a. Consequently, the dopants contained in the p-InP clad layer 7 and the high-resistance InP layers 6a can be prevented from diffusing each other. It is thus possible to restrain a reduction in the resistance of the isolation part and suppress an increase in the capacitance of the modulator part, whereby a high-speed operation of the laser with the optical modulator can be implemented.

Second Embodiment

FIGS. 13A and 13B are schematic drawings showing a laser with an optical modulator, according to a second embodiment. Here, FIG. 13A is a perspective view of the laser, and FIG. 13B is a schematic cross-sectional view showing a cross section taken along line I-I′ of FIG. 13A, respectively.

As shown in FIGS. 13A and 13B, the laser with the optical modulator according to the second embodiment also comprises an InP substrate 1, an n-InP clad layer 12, an active layer 2 (unillustrated in FIGS. 13A and 13B), an absorption layer 3, a p-InP clad layer 13, a mesa 5 including an active layer 2 and an absorption layer 3, current block layers 6 each having a high-resistance InP layer 6a and an n-InP layer 6b, a p-InP clad layer 7, a p-InGaAs contact layer 8, and process mesa trenches 9.

The laser further includes i-InGaAsP diffusion block layers 11 each formed between the high-resistance InP layer 6a and the n-InP layer 6b constituting the current block layer 6.

Since the i-InGaAsP diffusion block layer 11 is formed between the high-resistance InP layer 6a and the n-InP layer 6b in this way, dopants contained in the p-InP clad layer 7 and the high-resistance InP layers 6a can be inhibited from diffusing each other.

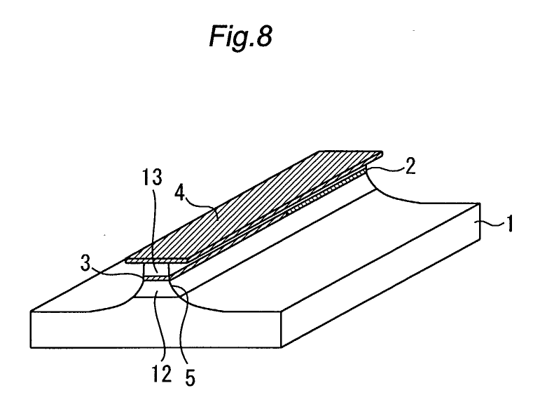

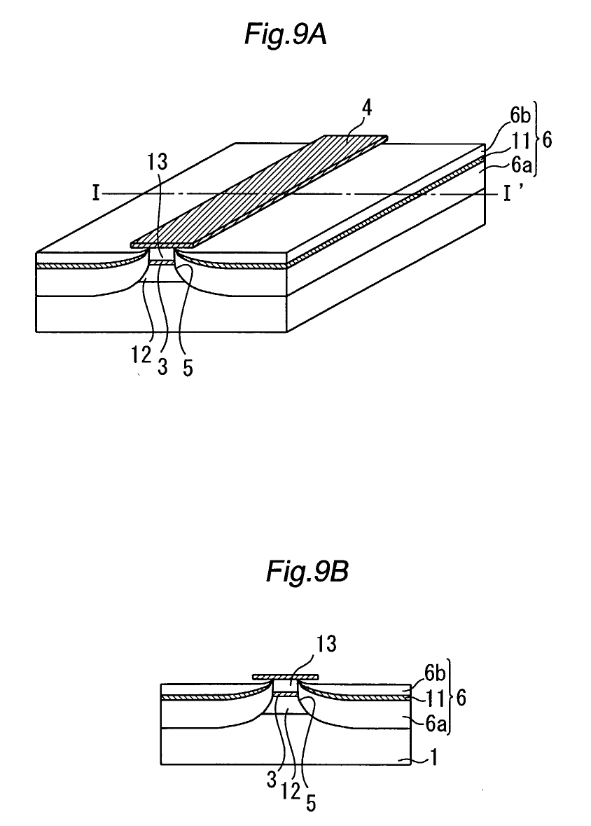

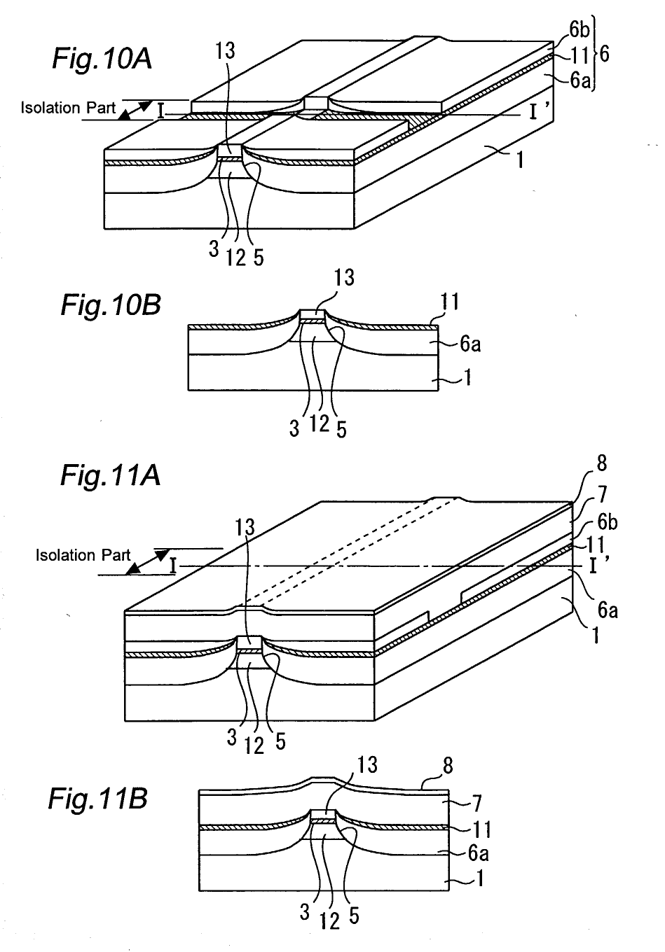

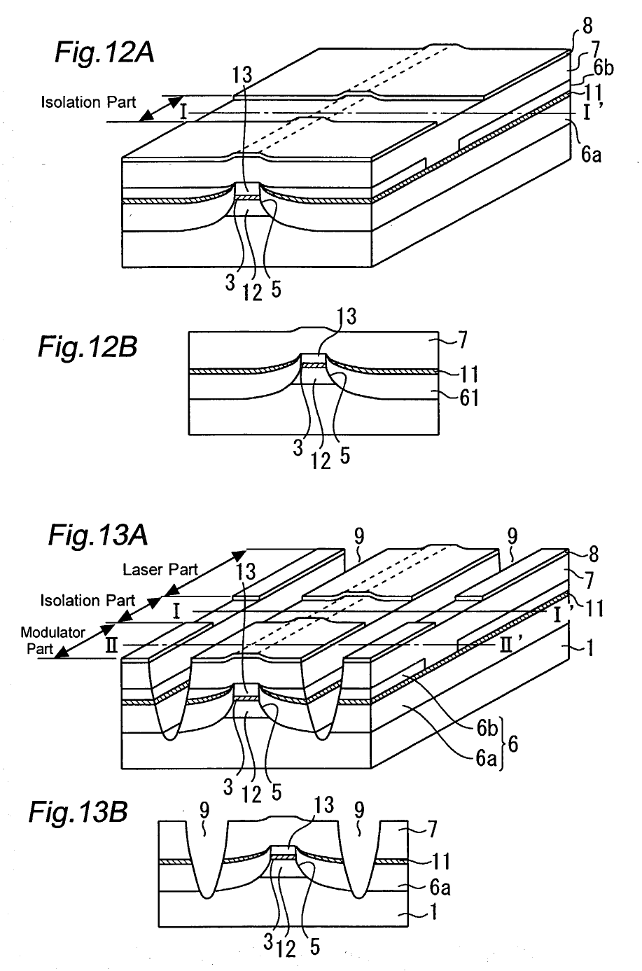

A method of manufacturing the laser according to the second embodiment will be explained below based on FIGS. 8 through 13. FIGS. 8 through 13 are respectively schematic drawings showing the manufacturing method of the laser according to the second embodiment in a process order, wherein FIG. 8, FIG. 9A, FIG. 10A, FIG. 11A, FIG. 12A and FIG. 13A are respectively perspective views of the laser. Further, FIG. 9B, FIG. 10B, FIG. 11B, FIG. 12B and FIG. 13B are schematic cross-sectional views respectively showing a cross section taken along I-I′ of FIG. 9A, a cross section taken along line I-I′ of FIG. 10A, a cross section taken along line I-I′ of FIG. 11A, a cross section taken along line I-I′ of FIG. 12A, and a cross section taken along line I-I′ of FIG. 13A. Here, the cross section taken along line I-I′ shows a cross section of an isolation part between the laser and a modulator part.

As shown in FIG. 8, a predetermined crystal layer containing an n-InP clad layer 12, an active layer 2 for the laser and an absorption layer 3 for its modulator, and a p-InP clad layer 13 is first epitaxially grown on an InP substrate 1. Afterwards, an insulating film 4 such as a silicon oxide film having a width of about 6 μm is formed thereon. With the insulating film 4 as a mask, a plateau type mesa 5 containing the active layer 2 and the absorption layer 3 is formed by wet etching using an etchant such as hydrogen bromide. At this time, for example, the depth of the mesa 5 results in about 4 μm, and the width of the active layer 2 or the absorption layer 3 reaches about 1.3 μm.

As shown in FIGS. 9A and 9B, the insulating film 4 used for the formation of the mesa 5 is next used as a selective growth mask. A high-resistance InP layer 6a, an i-InGaAsP diffusion block layer 11, and an n-InP layer 6b are continuously embedded in and grown on each side face of the mesa 5 as a current block layer 6 by a MOCVD method.

As shown in FIGS. 10A and 10B, the n-InP layers 6b of the isolation part are next removed by etching. The amount of etching is set to about 0.6 μm in a manner similar to the first embodiment. While the depth in this etching process is time-controlled where no i-InGaAsP diffusion block layers 11 are formed, the i-InGaAsP diffusion block layers 11 different in material are respectively inserted between the high-resistance InP layers 6a and the n-InP layers 6b in the second embodiment. Therefore, selective etching can be carried out through the use of the difference in etching rate between the n-InP layer 6b and the i-InGaAsP diffusion block layer 11. Accordingly, the n-InP layers 6b can be reliably removed with good reproducibility. A cross section of the isolation part subsequent to the removal of the n-InP layers 6b is represented as shown in FIG. 10B.

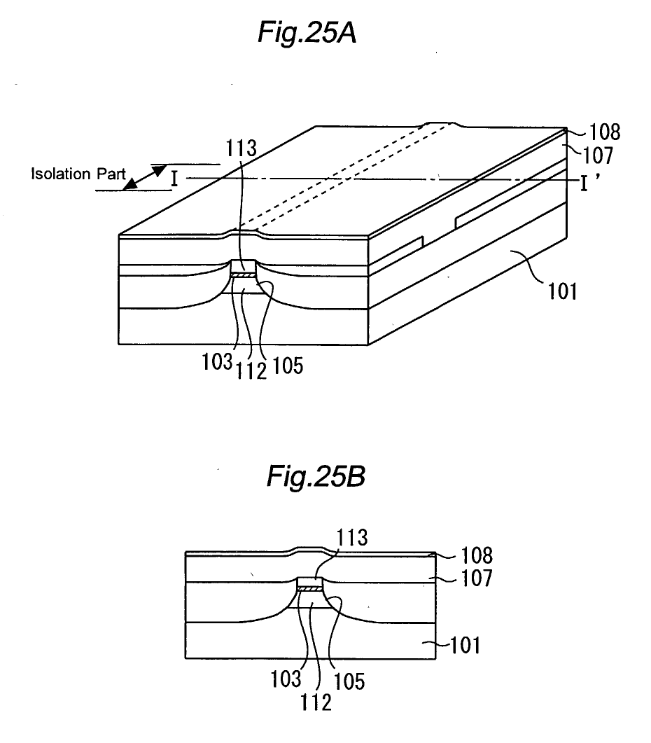

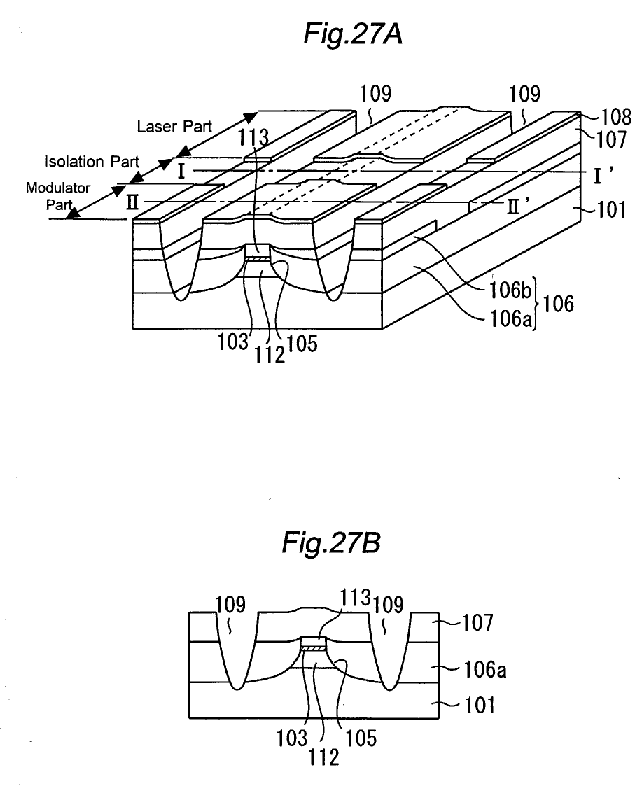

Process flows subsequent to the above are basically similar to the flows described in FIGS. 25 through 27. Namely, a p-InP clad layer 7 and a p-InGaAs contact layer 8 are grown over the whole surface of the wafer as shown in FIGS. 11A and 11B. Next, the p-InGaAs contact layer 8 of the isolation part is removed by etching as shown in FIGS. 12A and 12B. Finally, process mesa trenches 9 each having a width ranging from about 5 μm to about 7 μm are provided as shown in FIGS. 13A and 13B, whereby the laser with the optical modulator according to the second embodiment is completed.

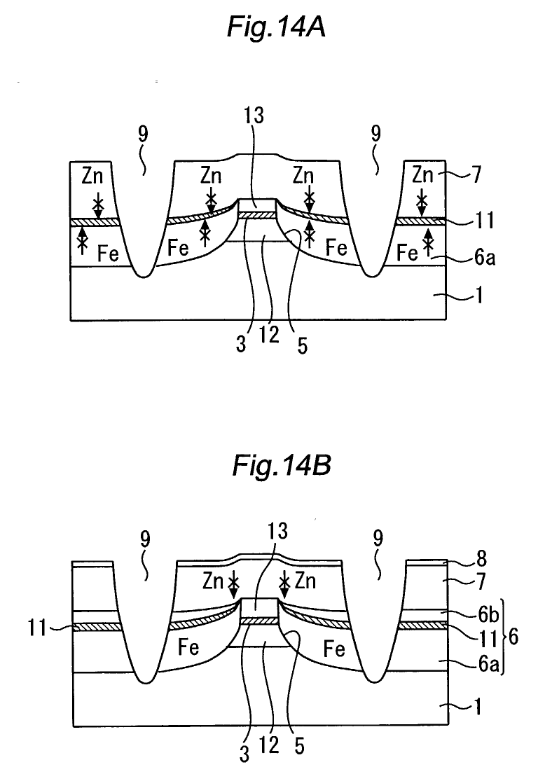

FIG. 14A is a schematic cross-sectional view showing a cross section of the isolation part of the completed laser in a manner similar to FIG. 13B. In the second embodiment, as shown in FIG. 14A, each of i-InGaAsP diffusion block layers 11 is inserted between an Fe-doped high-resistance InP layer 6a and a Zn-doped p-InP clad layer 7 in the isolation part. The i-InGaAsP diffusion block layer 11 serves as a diffusion block layer for absorbing Zn to diffuse from the p-InP clad layer 7 to each Fe-doped high-resistance InP layer 6a. As a result, the mutual diffusion of Zn and Fe can be prevented as shown in FIG. 14A. It is thus possible to restrain a reduction in isolation resistance between the laser and the modulator due to the diffusion of Zn into the high-resistance InP layer 6a.

FIG. 14B shows a cross section taken along line II-II′ of FIG. 13A and also illustrates a cross section of the modulator part of the completed laser with the optical modulator. Each of the i-InGaAsP diffusion block layer 11 is provided between the high-resistance InP layer 6a and nInP layer 6b of each current block layer 6 in the laser with the optical modulator according to the second embodiment. Therefore, Zn diffused from the p-InP clad layer 7 is absorbed into the i-InGaAsP diffusion block layer 11 high in solid solubility to thereby make it possible to inhibit the diffusion thereof into the Fe-doped high-resistance InP layer 6a. Accordingly, it is possible to suppress an increase in the capacitance of the modulator part due to the diffusion of Zn.

According to the second embodiment as described above, since each of the i-InGaAsP diffusion block layers 11 high in solid solubility for Zn is formed between the high-resistance InP layer 6a and the n-InP layer 6b, dopants contained in the p-InP clad layer 7 and the high-resistance InP layers 6a can be prevented from being diffused each other. It is thus possible to restrain a reduction in the isolation resistance between the laser and the modulator and suppress an increase in the capacitance of the modulator part due to the diffusion of Zn. Accordingly, a high-speed operation of the laser with the optical modulator can be realized.

Third Embodiment

FIGS. 20A and 20B are schematic drawings showing a laser with an optical modulator, according to a third embodiment. Here, FIG. 20A is a perspective view of the laser, and FIG. 20B is a schematic cross-sectional view showing a cross section taken along line I-I′ of FIG. 20A, respectively.

As shown in FIGS. 20A and 20B, the laser with the optical modulator according to the third embodiment also comprises an InP substrate 1, an n-InP clad layer 12, an active layer 2 (unillustrated in FIGS. 20A and 20B), an absorption layer 3, a p-InP clad layer 13, a mesa 5 including an active layer 2 and an absorption layer 3, current block layers 6 each having a high-resistance InP layer 6a and an n-InP layer 6b, a p-InP clad layer 7, a p-InGaAs contact layer 8, and process mesa trenches 9.

The laser further includes i-InGaAsP diffusion block layers 11 each formed as a first layer of the current block layer 6. The i-InGaAsP diffusion block layer 11 functions as a diffusion block layer.

Since the i-InGaAsP diffusion block layer 11 is formed at the first layer of each current block layer 6 in this way, each side face of the mesa 5 including the active layer 2 and the absorption layer 3 can be covered with the i-InGaAsP diffusion block layer 11. Thus, even when dopants contained in the p-InP clad layer 7 are diffused into the high-resistance InP layers 6a, the dopants can be inhibited from being diffused into the active layer 2 and the absorption layer 3.

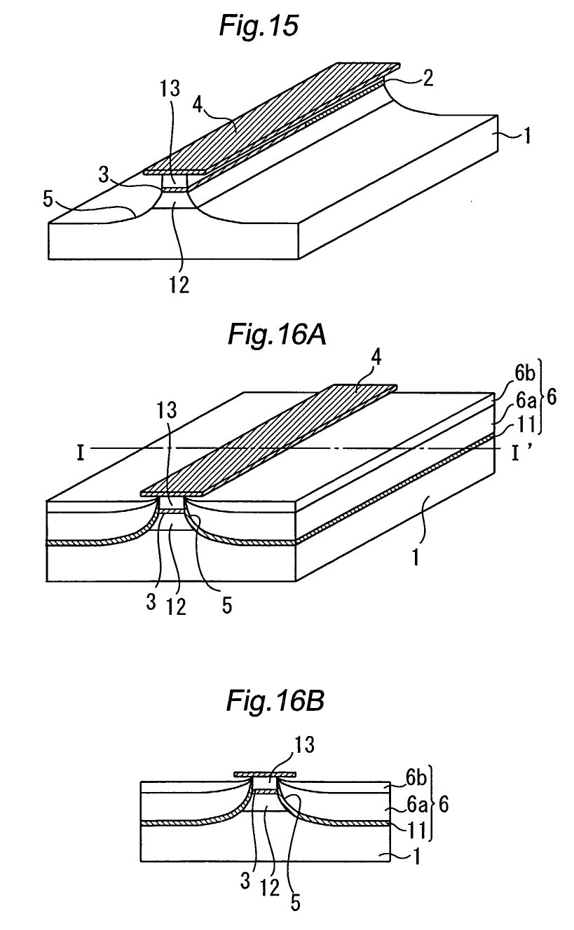

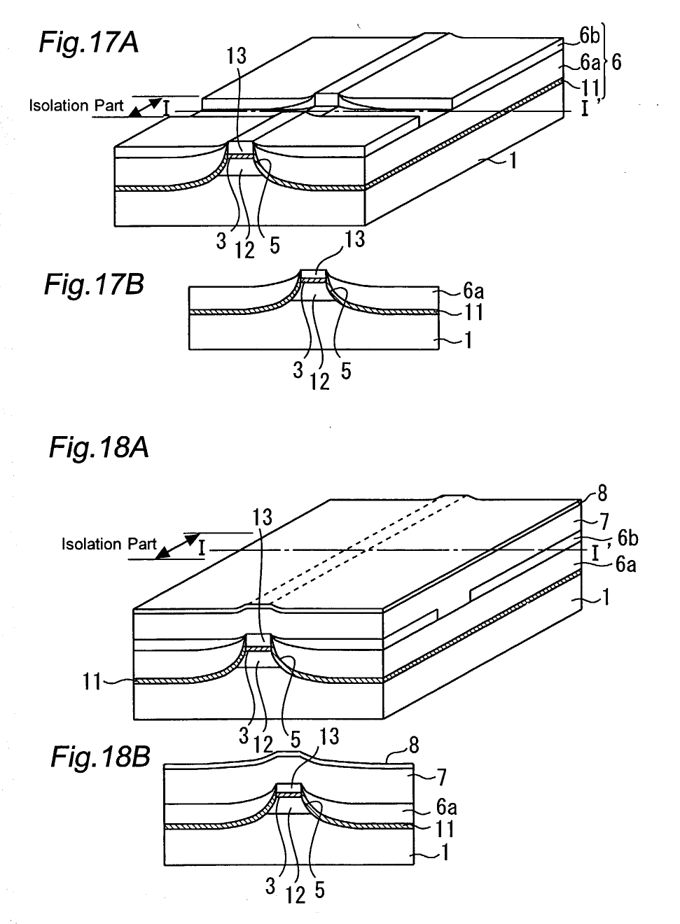

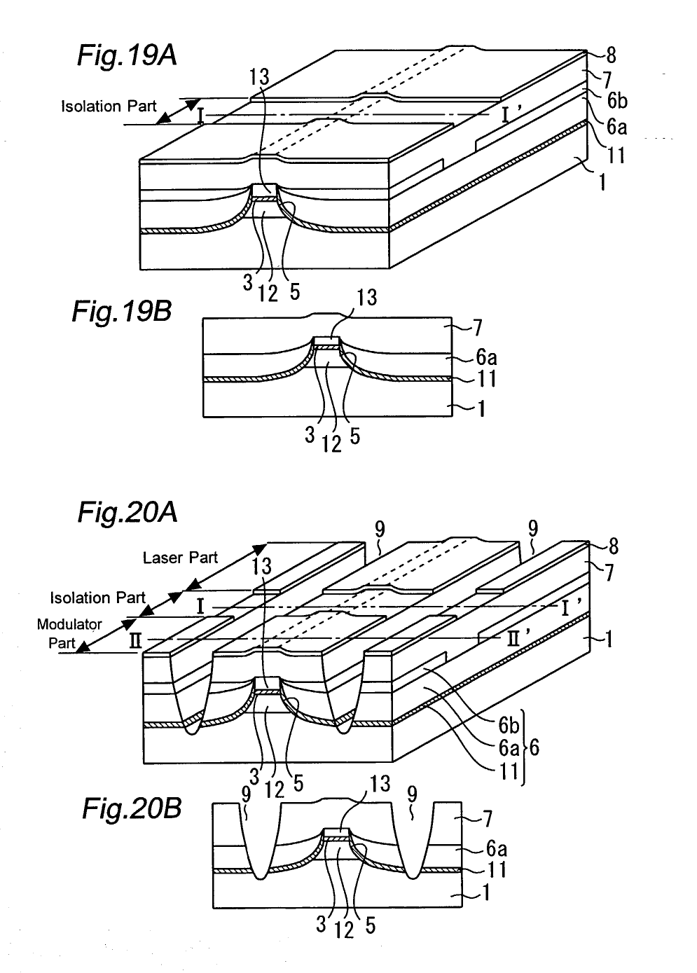

A method of manufacturing the laser according to the third embodiment will be explained below based on FIGS. 15 through 20. FIGS. 15 through 20 are respectively schematic drawings showing the manufacturing method of the laser according to the third embodiment in a process order, wherein FIG. 15, FIG. 16A, FIG. 17A, FIG. 18A, FIG. 19A and FIG. 20A are respectively perspective views of the laser. Further, FIG. 16B, FIG. 17B, FIG. 18B, FIG. 19B and FIG. 20B are schematic cross-sectional views respectively showing a cross section taken along I-I′ of FIG. 16A, a cross section taken along line I-I′ of FIG. 17A, a cross section taken along line I-I′ of FIG. 18A, a cross section taken along line I-I′ of FIG. 19A, and a cross section taken along line I-I′ of FIG. 20A. Here, the cross section taken along line I-I′ shows a cross section of an isolation part between the laser and a modulator part.

As shown in FIG. 15, a predetermined crystal layer containing an n-InP clad layer 2, an active layer 2 for the laser and an absorption layer 3 for the modulator, and a p-InP clad layer 13 is first epitaxially grown on an InP substrate 1. Afterwards, an insulating film 4 such as a silicon oxide film having a width of about 6 μm is formed thereon. With the insulating film 4 as a mask, a plateau type mesa 5 containing the active layer 2 and the absorption layer 3 is formed by wet etching using an etchant such as hydrogen bromide. At this time, for example, the depth of the mesa 5 results in about 4 μm, and the width of the active layer 2 or the absorption layer 3 reaches about 1.3 μm.

As shown in FIGS. 16A and 16B, the insulating film 4 used for the formation of the mesa 5 is next used as a selective growth mask. A current block layer 6 is grown on each side face of the mesa 5. At this time, each of i-InGaAsP diffusion block layers 11 each used as a first layer of the current block layer 6 is grown as a diffusion block layer. Thereafter, a high-resistance InP layer 6a, and an n-InP layer 6b are continuously embedded and grown subsequently to the growth of the i-InGaAsP diffusion block layers 11 by a MOCVD method.

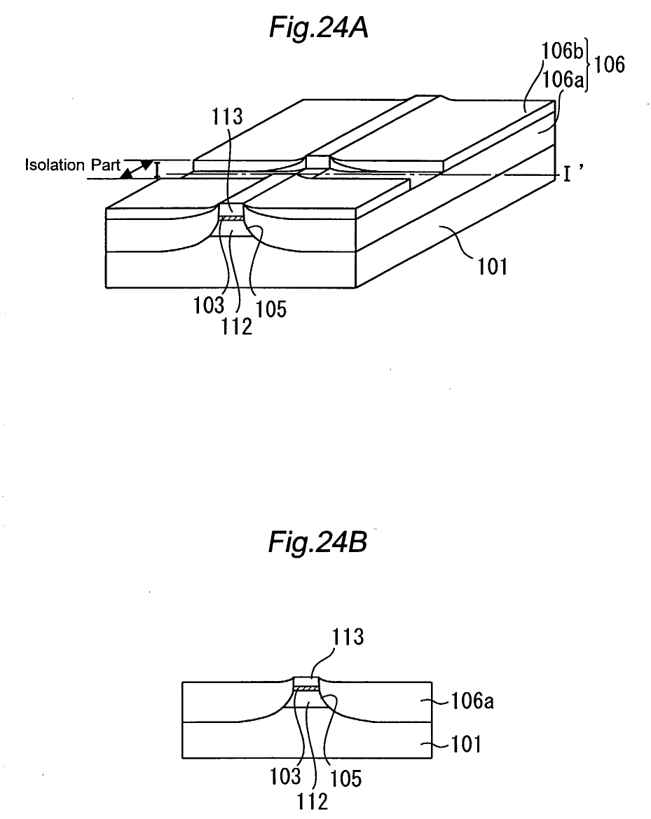

Process flows subsequent to the above are basically similar to the flows described in FIGS. 24 through 27. Namely, the n-InP layers 6b of the isolation part are removed by etching as shown in FIGS. 17A and 17B. Afterwards, a p-InP clad layer 7 and a p-InGaAs contact layer 8 are grown over the whole surface of the wafer as shown in FIGS. 18A and 18B.

Next, the p-InGaAs contact layer 8 of the isolation part is removed by etching as shown in FIGS. 19A and 19B. Finally, mesa trenches 9 each having a width ranging from 5 μm to 7 μm are provided as shown in FIGS. 20A and 20B, whereby the laser with the optical modulator according to the third embodiment is completed.

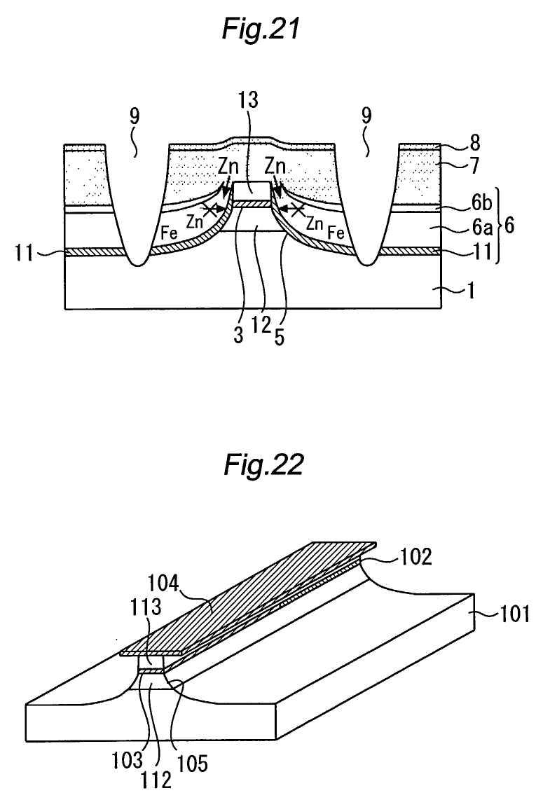

FIG. 21 shows a cross section taken along line II-II′ of FIG. 20A and also illustrates a cross section of the modulator part of the completed laser with the optical modulator. Each side face of the mesa 5 is covered with the i-InGaAsP diffusion block layer 11 high in solid solubility of Zn in the laser according to the present embodiment. Therefore, even if Zn contained in the p-InP clad layer 7 is diffused into the high-resistance InP layers 6a where the leading ends of the n-InP layers 6b of the current block layers 6 are spaced away from the AR mesa as shown in FIG. 21, the diffusion of the diffused Zn from the side faces of the mesa 5 to the respective layers such as the absorption layer 3, n-InP clad layer 2, p-InP clad layer 13, etc. can be inhibited. It is thus possible to suppress characteristic degradation such as a reduction in the efficiency of a device, and deterioration in reliability.

According to the third embodiment as described above, since the i-InGaAsP diffusion block layer 11 high in solid solubility for Zn is formed at the first layer of each current block layer 6, each side face of the mesa 5 including the active layer 2 and the absorption layer 3 can be covered with the i-InGaAsP diffusion block layer 11. Thus, even when the dopants contained in the p-InP clad layer 7 are diffused into each high-resistance InP layer 6a, the diffusion of the dopants into the mesa including the active layer 2 and the absorption layer 3 can be inhibited. It is thus possible to suppress characteristic degradation such as a reduction in the efficiency of a device, and deterioration in reliability.

Since the present invention is constructed as described above, it brings about such advantageous effects as shown below.

Since diffusion block layers are continuously formed on a mesa portion and current block layers, an impurity of a conductive layer can be prevented from being diffused into the current block layers. It is thus possible to inhibit a reduction in the resistance of each current block layer and realize a high-speed operation of a laser.

Covering the mesa portion including an absorption layer and the top of each current block layer with the diffusion block layer makes it possible to suppress an increase in the capacitance of a modulator part. Thus, a high-speed operation of a laser with an optical modulator can be implemented.

Since each of the current block layers comprises an insulative first layer and a second layer of conductivity type opposite to the conductive layer, the first layer can reliably block a current and the second layer can trap an impurity of the conductive layer. It is thus possible to suppress a reduction in the resistance of the first layer due to the impurity of the conductive layer.

Since the conductive layer and the first layer of the current block layer are constructed so as to oppose each other with the diffusion block layer interposed therebetween in the neighborhood of the boundary between the active layer and the absorption layer, it is possible to inhibit a reduction in the resistance of an isolation part between the active layer and the absorption layer due to the diffusion of the impurity of the conductive layer into the first layer. It is further possible to raise the resistance of the isolation part owing to the removal of the second layer of each current block slayer in the neighborhood of the boundary between the active layer and the absorption layer.

Since the diffusion block layer is formed between the first layer and second layer of each current block layer, the diffusion of the impurity of the conductive layer into the first layer of the current block layer can be inhibited. Further, the second layer is capable of trapping the impurity of the conductive layer. It is thus possible to suppress a reduction in the resistance of the current block layer and realize a high-speed operation of a laser.

Since it is possible to inhibit the diffusion of the impurity of the conductive layer into the first layer of the current block layer by virtue of the diffusion block layer, the isolation part between the active layer and the absorption layer can be rendered high in resistance. It is thus possible to realize a high-speed operation of a laser.

Since the second layer is removed in the neighborhood of the boundary between the active layer and the absorption layer, the isolation part between the active layer and the absorption layer can be brought to high resistance. It is also possible to allow the diffusion block layer to function as a stopper upon the removal of the second layer.

By applying the present invention to a semiconductor device wherein a first layer is an InP layer containing Fe and a conductive layer is an InP layer containing Zn as an impurity, it is possible to inhibit mutual diffusion of Fe of the first layer and Zn of the conductive layer.

Since the diffusion block layer is formed between each side of a mesa portion and its corresponding current block layer, the diffusion of an impurity of a conductive layer into the mesa portion can be inhibited. It is thus possible to suppress characteristic degradation such as a reduction in the efficiency of a device, and deterioration in reliability.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-144842, filed on May 20, 2002 including specification, claims, drawings and summary, on which the Convention priority of the present application is based, are incorporated herein by reference in its entirety.

1. A semiconductor device for producing laser light from an active layer, comprising:
a ridge-shaped mesa portion including said active layer;
current block layers formed so as to bury both sides of said mesa portion;
a diffusion block layer formed on said mesa portion and said current block layers in a continuous form; and
a conductive layer formed on said diffusion block layer and containing a predetermined impurity.

2. The semiconductor device according to claim 1, wherein said mesa portion further includes said active layer and an absorption layer for modulating said laser light, said absorption layer being formed in the same hierarchy as said active layer, adjacent to said active layer along a longitudinal direction thereof.

3. The semiconductor device according to claim 1, wherein said current block layers comprise a laminated layer of an insulative first layer for covering each side portion of said mesa portion, and a second layer of conductivity type opposite to said conductive layer, which is formed on said first layer.

4. The semiconductor device according to claim 3, wherein said second layer is removed in the vicinity of the boundary between said active layer and said absorption layer, and said conductive layer and said first layer are opposed to each other with said diffusion block layer interposed therebetween.

5. The semiconductor device according to claim 3, wherein said first layer is an InP layer containing Fe, and said conductive layer is an InP layer containing Zn as said impurity.

6. A semiconductor device for producing laser light from an active layer, comprising:
a ridge-shaped mesa portion including said active layer;
current block layers formed so as to bury both sides of said mesa portion; and
a conductive layer formed on said mesa portion and said current block layers and containing a predetermined impurity;
wherein said current block layers have an insulative first layer for covering each side portion of said mesa portion and a second layer of conductivity type opposite to said conductive layer, which is formed on said first layer, and
a diffusion block layer is formed between said first layer and said second layer.

7. The semiconductor device according to claim 6, wherein said mesa portion further includes said active layer and an absorption layer for modulating said laser light, said absorption layer being formed in the same hierarchy as said active layer, adjacent to said active layer along a longitudinal-direction thereof.

8. The semiconductor device according to claim 7, wherein said second layer is removed in the vicinity of the boundary between said active layer and said absorption layer, and said conductive layer and said first layer are opposed to each other with said diffusion block layer interposed therebetween.

9. The semiconductor device according to claim 6, wherein said first layer is an InP layer containing Fe, and said conductive layer is an InP layer containing Zn as said impurity.

10. A semiconductor device for producing laser light from an active layer, comprising:
a ridge-shaped mesa portion including said active layer;
current block layers formed so as to bury both sides of said mesa portion;
a diffusion block layer formed between at least each side portion of said mesa portion and said current block layer; and
a conductive layer formed over said mesa portion and said current block layers and containing a predetermined impurity.
